(19) United States
(12) Patent Application Publication
(10) Pub. No.: US 2026/0344411 A1
(43) Pub. Date: Oct. 29, 2026

(54) SEMICONDUCTOR DEVICE AND METHOD OF MANUFACTURING THE SAME

(71) Applicant: Renesas Electronics Corporation, Tokyo (JP)

(72) Inventor: Hiromichi TAKAOKA, Tokyo (JP)

(21) Appl. No.: 19/558,049

(22) Filed: Mar. 5, 2026

(30) Foreign Application Priority Data
Apr. 24, 2025 (JP) 2025-072159

(51) Int. Cl. H10W 20/49; H10D 64/66; H10D 84/80; H10W 20/44

(52) U.S. Cl. CPC H10W 20/493; H10D 64/661; H10D 84/817; H10W 20/4451

(57) ABSTRACT

A semiconductor device includes a transistor and an electric fuse element. The transistor includes a gate electrode. The gate electrode is a first polysilicon layer. The electric fuse element includes a second polysilicon layer and a metal silicide layer formed on the second polysilicon layer. An average dopant concentration of the second polysilicon layer is lower than an average dopant concentration of the first polysilicon layer.

### CROSS-REFERENCE TO RELATED APPLICATIONS

The disclosure of Japanese Patent Application No. 2025-072159 filed on Apr. 24, 2025, including the specification, drawings and abstract is incorporated herein by reference in its entirety.

### BACKGROUND

This disclosure relates to semiconductor devices and a method of manufacturing the same, and can be suitably used, for example, for semiconductor devices equipped with electric fuse elements and the method of manufacturing the same.

### There are disclosed techniques listed below.

### Patent Document 1 Japanese Unexamined Patent Application Publication No. 2024-73007

Patent Document 1 discloses a semiconductor device including an electric fuse portion and a cutting transistor. The electric fuse portion includes a polysilicon layer doped with n-type dopant and a silicide layer disposed on the polysilicon layer. The cutting transistor is connected to the electric fuse portion. When the cutting transistor is turned on and current is supplied to the electric fuse portion, the polysilicon layer is melted and cut. Thus, the conductivity state of the electric fuse portion changes.

### SUMMARY

Further miniaturization is demanded for the semiconductor device disclosed in Patent Document 1. Other objects and novel features will become apparent from the description of this specification and the accompanying drawings.

According to one embodiment, a semiconductor device includes a transistor and an electric fuse element. The transistor includes a gate electrode. The gate electrode is a first polysilicon layer. The electric fuse element includes a second polysilicon layer and a metal silicide layer formed on the second polysilicon layer. An average dopant concentration of the second polysilicon layer is lower than an average dopant concentration of the first polysilicon layer.

According to the embodiment, the semiconductor device can be miniaturized.

### BRIEF DESCRIPTION OF THE DRAWINGS

FIG. 1 is a plan view showing a configuration in the chip state of semiconductor devices from a first embodiment to a seventh embodiment.

FIG. 2 is a schematic partial enlarged cross-sectional view of the transistor region of semiconductor devices from first embodiment to fourth embodiment and sixth embodiment.

FIG. 3 is a diagram showing a part of the electric fuse circuit of semiconductor devices from first embodiment to third embodiment and fifth embodiment to seventh embodiment.

FIG. 4 is a schematic partial enlarged plan view of the electric fuse circuit region of semiconductor devices from first embodiment to seventh embodiment.

FIG. 5 is a schematic partial enlarged cross-sectional view at the sectional line V-V shown in FIG. 4 of the electric fuse circuit region of semiconductor devices from first embodiment to fourth embodiment, sixth embodiment, and seventh embodiment.

FIG. 6 is a diagram showing the dopant concentration distribution of the gate electrode in the transistor region from first embodiment and third embodiment to sixth embodiment, and the dopant concentration distribution of the polysilicon layer in the electric fuse circuit region.

FIG. 7 is a schematic partial cross-sectional view showing one step of the manufacturing method of the semiconductor device of first embodiment.

FIG. 8 is a schematic partial cross-sectional view showing the next step of the step shown in FIG. 7 in the manufacturing method of the semiconductor device of first embodiment.

FIG. 9 is a schematic partial cross-sectional view showing the next step of the step shown in FIG. 8 in the manufacturing method of the semiconductor device of first embodiment.

FIG. 10 is a schematic partial cross-sectional view showing the next step of the step shown in FIG. 9 in the manufacturing method of the semiconductor device of first embodiment.

FIG. 11 is a schematic partial cross-sectional view showing the next step of the step shown in FIG. 10 in the manufacturing method of the semiconductor device of first embodiment.

FIG. 12 is a schematic partial cross-sectional view showing the next step of the step shown in FIG. 11 in the manufacturing method of the semiconductor device of first embodiment.

FIG. 13 is a schematic partial cross-sectional view showing the next step of the step shown in FIG. 12 in the manufacturing method of the semiconductor device of first embodiment.

FIG. 14 is a schematic partial cross-sectional view showing the next step of the step shown in FIG. 13 in the manufacturing method of the semiconductor device of first embodiment.

FIG. 15 is a schematic partial cross-sectional view showing the next step of the step shown in FIG. 14 in the manufacturing method of the semiconductor device of first embodiment.

FIG. 16 is a schematic partial cross-sectional view showing the next step of the step shown in FIG. 15 in the manufacturing method of the semiconductor device of first embodiment.

FIG. 17 is a schematic partial cross-sectional view showing the next step of the step shown in FIG. 16 in the manufacturing method of the semiconductor device of first embodiment.

FIG. 18 is a schematic partial enlarged plan view of the electric fuse circuit region from first embodiment to seventh embodiment after current is applied.

FIG. 19 is a diagram showing the dopant concentration distribution of the gate electrode in the transistor region of the second modification of first embodiment and the dopant concentration distribution of the polysilicon layer in the electric fuse circuit region.

FIG. 20 is a diagram showing the dopant concentration distribution of the gate electrode in the transistor region of second embodiment and the dopant concentration distribution of the polysilicon layer in the electric fuse circuit region.

FIG. 21 is a schematic partial cross-sectional view showing one step of the manufacturing method of the semiconductor device of second embodiment.

FIG. 22 is a schematic partial cross-sectional view showing one step of the manufacturing method of the semiconductor device of third embodiment.

FIG. 23 is a diagram showing a part of the electric fuse circuit of the semiconductor device of fourth embodiment.

FIG. 24 is a schematic partial enlarged plan view of the electric fuse circuit region in the semiconductor device of fourth embodiment.

FIG. 25 is a schematic partial enlarged cross-sectional view at the sectional line XXV-XXV shown in FIG. 24 of the electric fuse circuit region of the semiconductor device of fourth embodiment.

FIG. 26 is a diagram showing a part of the electric fuse circuit of the first modification of the semiconductor device of fourth embodiment.

FIG. 27 is a diagram showing a part of the electric fuse circuit of the second modification of the semiconductor device of fourth embodiment.

FIG. 28 is a schematic partial enlarged cross-sectional view of the transistor region and electric fuse circuit region of the semiconductor device of fifth embodiment.

FIG. 29 is a schematic partial cross-sectional view showing one step of the manufacturing method of the semiconductor device of fifth embodiment.

FIG. 30 is a schematic partial cross-sectional view showing one step of the manufacturing method of the semiconductor device of sixth embodiment.

FIG. 31 is a schematic partial enlarged cross-sectional view of the transistor region of the semiconductor device of seventh embodiment.

FIG. 32 is a diagram showing the dopant concentration distribution of the gate electrode in the transistor region of seventh embodiment and the dopant concentration distribution of the polysilicon layer in the electric fuse circuit region.

FIG. 33 is a schematic partial cross-sectional view showing the next step of the step shown in FIG. 32 in the manufacturing method of the semiconductor device of seventh embodiment.

FIG. 34 is a schematic partial cross-sectional view showing the next step of the step shown in FIG. 33 in the manufacturing method of the semiconductor device of seventh embodiment.

FIG. 35 is a schematic partial cross-sectional view showing the next step of the step shown in FIG. 34 in the manufacturing method of the semiconductor device of seventh embodiment.

FIG. 36 is a schematic partial cross-sectional view showing the next step of the step shown in FIG. 35 in the manufacturing method of the semiconductor device of seventh embodiment.

FIG. 37 is a schematic partial cross-sectional view showing the next step of the step shown in FIG. 36 in the manufacturing method of the semiconductor device of seventh embodiment.

FIG. 38 is a schematic partial cross-sectional view showing the next step of the step shown in FIG. 37 in the manufacturing method of the semiconductor device of seventh embodiment.

FIG. 39 is a schematic partial cross-sectional view showing the next step of the step shown in FIG. 38 in the manufacturing method of the semiconductor device of seventh embodiment.

### DETAILED DESCRIPTION

Hereinafter, embodiments of the present disclosure will be described in detail with reference to the drawings. In the specification and the drawings, the same or corresponding components are denoted by the same reference numerals, and a repetitive description thereof is not repeated. In the drawings, for convenience of description, the configuration may be omitted or simplified. At least part of each embodiment and modified example may be combined freely.

### FIRST EMBODIMENT

### STRUCTURE OF SEMICONDUCTOR DEVICE

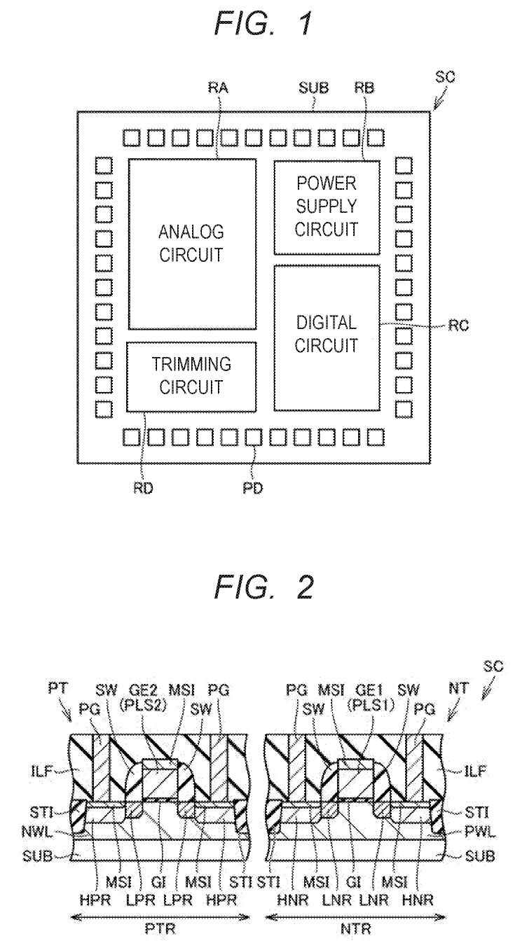

Referring to FIGS. 1-6, the semiconductor device SC of first embodiment will be described. The semiconductor device SC of first embodiment is a semiconductor chip. The semiconductor device SC is not limited to semiconductor chips; it may also be a semiconductor wafer before division into semiconductor chips, or a semiconductor package where the semiconductor chip is sealed with resin. The semiconductor device SC may be, for example, a microcontroller.

Referring to FIG. 1, the semiconductor device SC includes a semiconductor substrate SUB. The semiconductor substrate SUB is, for example, a single crystal silicon (Si) substrate. The semiconductor substrate SUB includes, for example, an analog circuit region RA, a power supply circuit region RB, a digital circuit region RC, and a trimming circuit region RD. The semiconductor device SC includes a transistor NT (see FIG. 2), a transistor PT (see FIG. 2), a trimming circuit TRC, and pad electrodes PD.

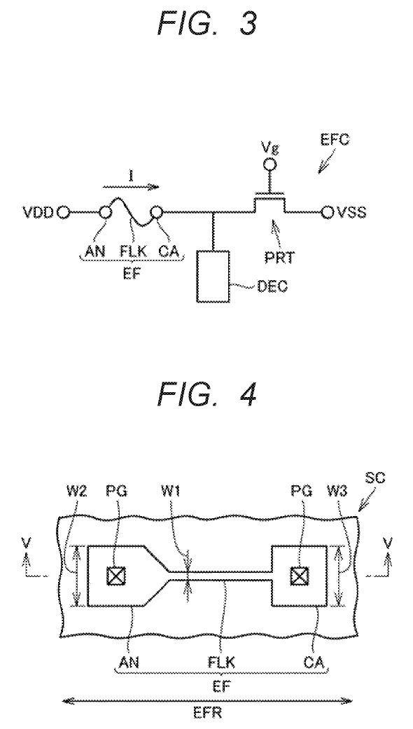

The transistor NT and the transistor PT are formed in the analog circuit region RA, the power supply circuit region RB, the digital circuit region RC, and the trimming circuit region RD. The trimming circuit TRC is disposed in the trimming circuit region RD. The pad electrodes PD are arranged around the analog circuit region RA, the power supply circuit region RB, the digital circuit region RC, and the trimming circuit region RD. The pad electrodes PD are electrically connected to the electric elements (such as transistor NT, transistor PT, and programming transistor PRT (see FIG. 3)) in the semiconductor device SC.

Referring to FIG. 2, the transistor NT and the transistor PT will be described. The transistor NT is formed in the n-type transistor region NTR of the semiconductor substrate SUB. The transistor PT is formed in the p-type transistor region PTR of the semiconductor substrate SUB.

Referring to FIG. 2, the transistor NT is, for example, an N-channel type metal-insulator-semiconductor field-effect transistor (MISFET). The transistor NT includes a p-type well region PWL, an n-type region HNR, an n-type region LNR, a metal silicide layer MSI, a gate insulating film GI, a gate electrode GE1, and a sidewall spacer SW.

The p-type well region PWL is formed at the upper surface of the semiconductor substrate SUB. An element isolation region STI is formed in the well region PWL. The element isolation region STI is embedded in a trench formed at the upper surface of the semiconductor substrate SUB. The insulating film is, for example, a silicon oxide film.

The gate insulating film GI is formed on the well region PWL. The gate insulating film GI is, for example, a silicon oxide film. The gate electrode GE is formed on the gate insulating film GI. The gate electrode GE1 is, for example, a polysilicon layer PLS1 doped with an n-type dopant (e.g., phosphorus (P) or arsenic (As)). In this specification, polysilicon refers to polycrystalline silicon. A sidewall spacer SW is formed on the side surface of the gate electrode GE1. The sidewall spacer SW has, for example, a silicon oxide film and a silicon nitride film.

The n-type region HNR and the n-type region LNR are formed in the well region PWL. The n-type region HNR is the source region and the drain region of the transistor NT. The n-type region HNR is formed between the element isolation region STI and the n-type region LNR. The n-type dopant concentration of the n-type region HNR is higher than the n-type dopant concentration of the n-type region LNR. The n-type region LNR is the extension region of the source region and the extension region of the drain region of the transistor NT. The n-type region LNR is formed under the sidewall spacer SW. The n-type region LNR is formed between the n-type region HNR and the gate insulating film GI. The n-type region LNR is formed shallower than the n-type region HNR. The transistor NT has an LDD (Lightly Doped Drain) structure. The n-type region LNR mitigates the hot carrier effect.

A metal silicide layer MSI is formed on the gate electrode GE1 and the n-type region HNR. The metal silicide layer MSI and the gate electrode GE1 are laminated in the thickness direction of the semiconductor substrate SUB. In this specification, the thickness direction of the semiconductor substrate SUB means a direction perpendicular to the upper surface of the semiconductor substrate SUB. The metal silicide layer MSI is formed of, for example, cobalt silicide, nickel silicide, or nickel platinum silicide.

With reference to FIG. 2, the transistor PT is, for example, a P-channel type MISFET. The transistor PT has a similar configuration to the transistor NT, but instead of the p-type well region PWL, n-type region HNR, n-type region LNR, and gate electrode GE1 of the transistor NT, the transistor PT includes an n-type well region NWL, a p-type region HPR, a p-type region LPR, and a gate electrode GE2.

The n-type well region NWL is formed at the upper surface of the semiconductor substrate SUB. An element isolation region STI is formed in the well region NWL.

The gate insulating film GI is formed on the well region NWL. The gate electrode GE is formed on the gate insulating film GI. The gate electrode GE2 is, for example, a polysilicon layer PLS2 doped with a p-type dopant (e.g., boron (B)). A sidewall spacer SW is formed on the side surface of the gate electrode GE2.

The p-type region HPR and the p-type region LPR are formed in the well region NWL. The p-type region HPR is the source region and the drain region of transistor PT. The p-type region HPR is formed between the element isolation region STI and the p-type region LPR. The p-type dopant concentration of the p-type region HPR is higher than the p-type dopant concentration of the p-type region LPR. The p-type region LPR is the extension region of the source region and the extension region of the drain region of transistor PT. The p-type region LPR is formed under the sidewall spacer SW. The p-type region LPR is formed between the p-type region HPR and the gate insulating film GI. The p-type region LPR is formed shallower than the p-type region HPR. The transistor PT has an LDD structure. The p-type region LPR mitigates the hot carrier effect.

A metal silicide layer MSI is formed on the gate electrode GE2 and the p-type region HPR. The metal silicide layer MSI and the gate electrode GE2 are laminated in the thickness direction of the semiconductor substrate SUB.

With reference to FIGS. 1 and 3-5, the trimming circuit TRC includes the electric fuse circuit EFC. The electric fuse circuit EFC includes an electric fuse element EF, a programming transistor PRT, and a determination circuit DEC.

The electric fuse element EF is used to switch electric connections in the semiconductor device SC and to reconfigure circuits included in the semiconductor device SC. The electric fuse element EF is formed on the electric fuse circuit region EFR of the semiconductor substrate SUB. The electric fuse circuit region EFR is part of the trimming circuit region RD (see FIG. 1).

The electric fuse element EF includes a fuse link FLK, an anode terminal AN, and a cathode terminal CA. The anode terminal AN is connected to the first end of the fuse link FLK. The cathode terminal CA is connected to the second end of the fuse link FLK opposite to the first end. The width W1 of the fuse link FLK is smaller than the width W2 of the anode terminal AN and smaller than the width W3 of the cathode terminal CA. The width W1 of the fuse link FLK is, in plan view of the upper surface of the semiconductor substrate SUB, the length of the fuse link FLK in the short direction. The width W2 of the anode terminal AN is, in plan view of the upper surface of the semiconductor substrate SUB, the length of the anode terminal AN in the short direction. The width W3 of the cathode terminal CA is, in plan view of the upper surface of the semiconductor substrate SUB, the length of the cathode terminal CA in the short direction.

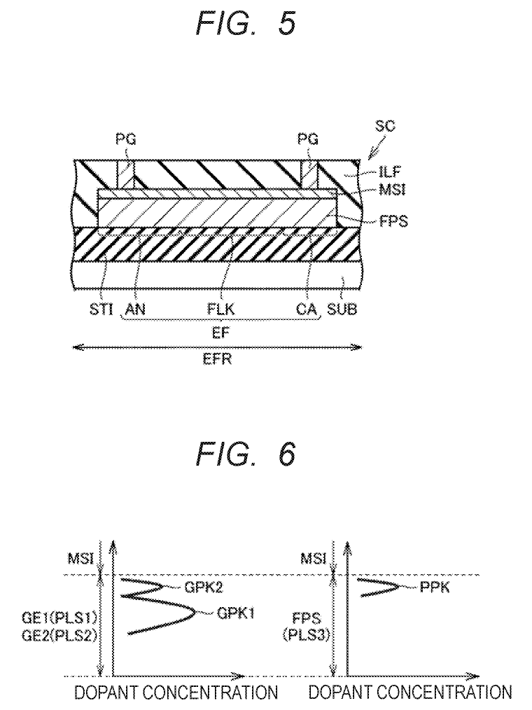

With reference to FIGS. 4 and 5, the electric fuse element EF is formed on the element isolation region STI in the electric fuse circuit region EFR. Each of the fuse link FLK, the anode terminal AN, and the cathode terminal CA includes a polysilicon layer FPS and a metal silicide layer MSI.

The polysilicon layer FPS is a polysilicon layer doped with a p-type dopant (e.g., boron (B)) and has conductivity. The polysilicon layer FPS is formed on the element isolation region STI. The metal silicide layer MSI is formed on the polysilicon layer FPS. The metal silicide layer MSI and the polysilicon layer FPS are laminated in the thickness direction of the semiconductor substrate SUB. The polysilicon layer FPS is formed between the element isolation region STI and the metal silicide layer MSI. The electric resistance of the metal silicide layer MSI is smaller than the electric resistance of the polysilicon layer FPS.

The anode terminal AN is connected to the power supply voltage VDD. The cathode terminal CA is connected to the ground potential VSS via the programming transistor PRT. The programming transistor PRT controls the current I supplied to the electric fuse element EF. The programming transistor PRT may be configured as the n-type transistor NT or the p-type transistor PT shown in FIG. 2. The cathode terminal CA and the programming transistor PRT are connected to the determination circuit DEC. The determination circuit DEC determines the conduction state of the electric fuse element EF (change in the electric resistance of the electric fuse element EF).

The average dopant concentration of the polysilicon layer FPS is lower than the average dopant concentration of the polysilicon layer PLS1 of the gate electrode GE1. The average dopant concentration of the polysilicon layer FPS is, for example, 20% or less of the average dopant concentration of the polysilicon layer PLS1 of the gate electrode GE1. The average dopant concentration of the polysilicon layer FPS is lower than the average dopant concentration of the polysilicon layer PLS2 of the gate electrode GE2. The average dopant concentration of the polysilicon layer FPS is, for example, 20% or less of the average dopant concentration of the polysilicon layer PLS2 of the gate electrode GE2. In this specification, the average dopant concentration of the polysilicon layer is the average value of the dopant concentration of the polysilicon layer in the thickness direction. Therefore, the sheet resistance of the polysilicon layer FPS is greater than the sheet resistance of the gate electrode GE1. The sheet resistance of the polysilicon layer FPS is greater than the sheet resistance of the gate electrode GE2.

With reference to FIG. 6, the polysilicon layer FPS has a single peak PPK of dopant concentration in the thickness direction. The polysilicon layer PLS2 of the gate electrode GE2 has a first peak GPK1 and a second peak GPK2 of dopant concentration in the thickness direction. The dopant concentration of the first peak GPK1 is higher than the dopant concentration of the second peak GPK2.

The peak dopant concentration of the polysilicon layer FPS is lower than the peak dopant concentration of the polysilicon layer PLS2 of the gate electrode GE2. The peak dopant concentration of the polysilicon layer FPS is the dopant concentration of the polysilicon layer FPS at the peak PPK. The peak dopant concentration of the polysilicon layer PLS2 is the dopant concentration of the polysilicon layer PLS2 at the first peak GPK1. The peak value of dopant concentration at the peak dopant concentration of the polysilicon layer FPS is, for example, 20% or less of the peak dopant concentration of the gate electrode GE2.

The depth at which the dopant concentration of the polysilicon layer FPS is maximum (depth of peak PPK) is shallower than the depth at which the dopant concentration of the polysilicon layer PLS2 of the gate electrode GE2 is maximum (depth of first peak GPK1). The depth of the second peak GPK2 is similar to the depth of peak PPK and shallower than the depth of the first peak GPK1. In this specification, the depth of peak PPK refers to the depth of peak PPK from the metal silicide layer MSI on the polysilicon layer FPS in the thickness direction of the semiconductor substrate SUB. The depth of the first peak GPK1 refers to the depth of the first peak GPK1 from the metal silicide layer MSI on the gate electrode GE2 in the thickness direction of the semiconductor substrate SUB. The depth of the second peak GPK2 refers to the depth of the second peak GPK2 from the metal silicide layer MSI on the gate electrode GE2 in the thickness direction of the semiconductor substrate SUB.

The distribution of dopant (n-type dopant) in the polysilicon layer PLS1 of the gate electrode GE1 is similar to the distribution of dopant (p-type dopant) in the polysilicon layer PLS2 of the gate electrode GE2.

Referring to FIGS. 2 and 5, an interlayer insulating film ILF is formed on the transistor NT, the transistor PT, and the electric fuse element EF. The interlayer insulating film ILF is, for example, a silicon oxide film. Contact holes are formed in the interlayer insulating film ILF. The plug PG is formed in each of the contact holes. The plug PG is formed of, for example, a barrier metal film made from a titanium film, a titanium nitride film, or a laminated film thereof, and a conductive film mainly containing tungsten. A wiring line (not shown) is formed on the interlayer insulating film ILF and the plug PG.

In the n-type transistor region NTR, the plug PG is connected to the metal silicide layer MSI formed on the n-type region HNR. The plug PG is electrically connected to the n-type region HNR via the metal silicide layer MSI. In the p-type transistor region PTR, the plug PG is connected to the metal silicide layer MSI formed on the p-type region HPR. The plug PG is electrically connected to the p-type region HPR via the metal silicide layer MSI. In the electric fuse circuit region EFR, the plug PG is connected to the metal silicide layer MSI of the electric fuse element EF.

### MANUFACTURING METHOD OF SEMICONDUCTOR DEVICE SC

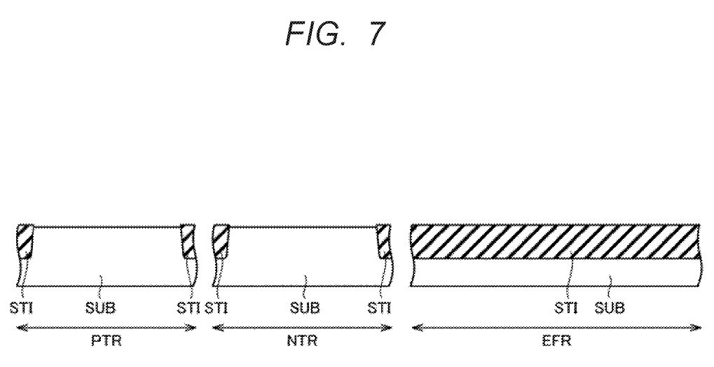

Referring to FIGS. 7-17 , an example of the manufacturing method of semiconductor device SC of the first embodiment will be described.

Referring to FIG. 7, trenches are formed using photolithography and etching process in the n-type transistor region NTR, the p-type transistor region PTR, and the electric fuse circuit region EFR of the semiconductor substrate SUB. Next, an insulating film is formed in the trenches and on the upper surface of the semiconductor substrate SUB. The trenches are embedded with an insulating film. The insulating film is, for example, a silicon oxide film. The insulating film outside the trenches is removed using the CMP (Chemical Mechanical Polishing) method. Then, element isolation region STI is formed.

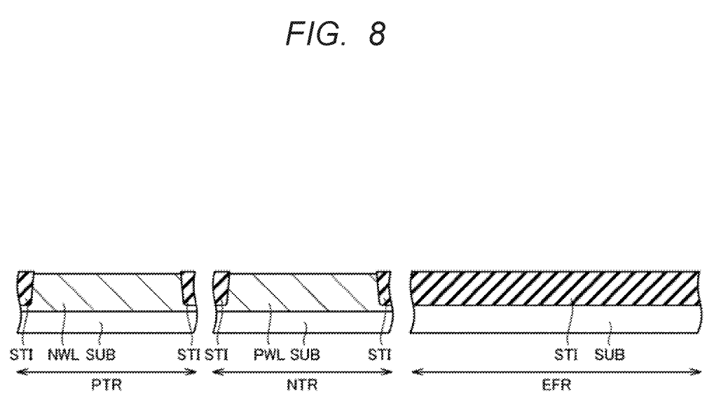

Referring to FIG. 8, using ion implantation method, p-type dopant (for example, boron (B)) is doped into the n-type transistor region NTR to form a p-type well region PWL. Since the p-type transistor region PTR and the electric fuse circuit region EFR are covered with a mask (not shown) during doping of the p-type dopant, the p-type dopant is not doped into the p-type transistor region PTR and the electric fuse circuit region EFR.

Using ion implantation method, n-type dopant (for example, phosphorus (P) or arsenic (As)) is doped into the p-type transistor region PTR to form an n-type well region NWL. Since the n-type transistor region NTR and the electric fuse circuit region EFR are covered with a mask (not shown) during doping of the n-type dopant, the n-type dopant is not doped into the n-type transistor region NTR and the electric fuse circuit region EFR.

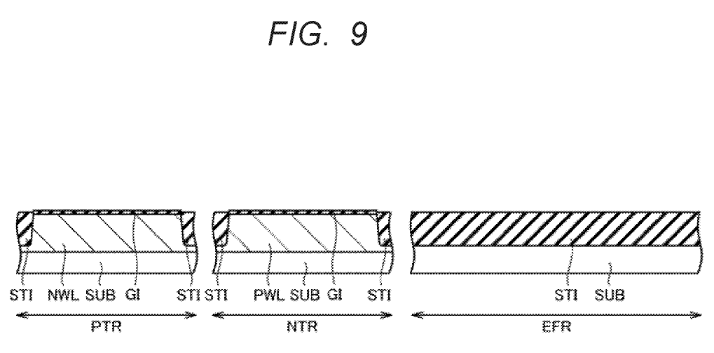

Referring to FIG. 9, for example, the semiconductor substrate SUB is heat-treated in an oxygen-containing atmosphere, forming the gate insulating film GI on the regions of the well region NWL and the well region PWL of the semiconductor substrate SUB exposed from the element isolation regions STI.

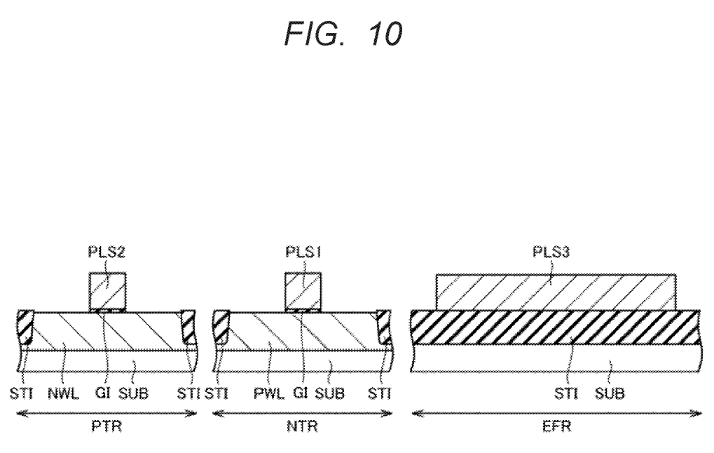

Referring to FIG. 10, for example, using the CVD method, a polysilicon layer (not shown) is formed on the gate insulating film GI on the n-type transistor region NTR, the gate insulating film GI on the p-type transistor region PTR, and the element isolation regions STI in the electric fuse circuit region EFR. The polysilicon layer is patterned using photolithography and etching processes. Thus, the polysilicon layer PLS1 is formed on the gate insulating film GI in the n-type transistor region NTR. The polysilicon layer PLS2 is formed on the gate insulating film GI in the p-type transistor region PTR. The polysilicon layer PLS3 is formed on the element isolation regions STI in the electric fuse circuit region EFR. Using the polysilicon layer PLS1 and the polysilicon layer PLS2 as etching masks, the portions of the gate insulating film GI exposed from the polysilicon layer PLS1 and the polysilicon layer PLS2 in the n-type transistor region NTR and the p-type transistor region PTR are removed.

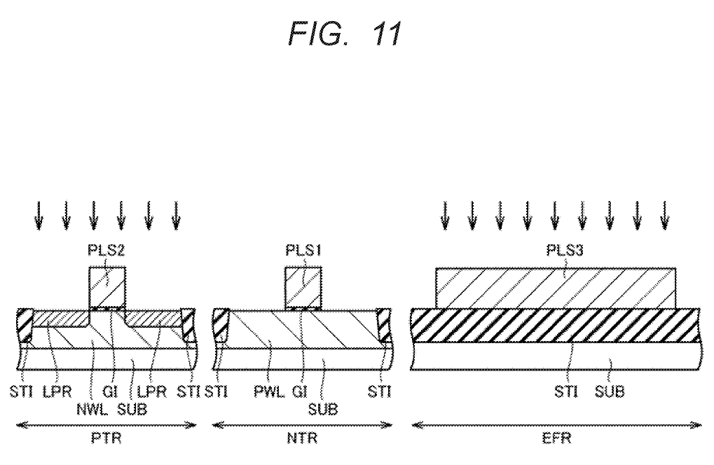

Referring to FIG. 11, using ion implantation method, p-type dopant (for example, boron (B)) is doped into the n-type well region NWL in the p-type transistor region PTR, the polysilicon layer PLS2 on the p-type transistor region PTR, and the polysilicon layer PLS3 on the electric fuse circuit region EFR. A p-type region LPR is formed in the p-type transistor region PTR. The peak PPK of dopant concentration in the polysilicon layer FPS (see FIG. 6) and the second peak GPK2 of dopant concentration in the polysilicon layer PLS2 (see FIG. 6) are formed by the ion implantation step shown in FIG. 11. Since the n-type transistor region NTR is covered with a mask (not shown) during doping of the p-type dopant, the p-type dopant is not doped into the n-type transistor region NTR.

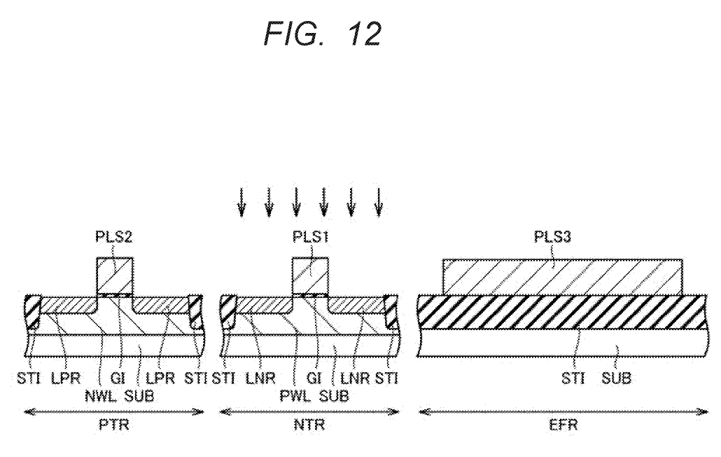

Referring to FIG. 12, using ion implantation method, n-type dopant (for example, phosphorus (P) or arsenic (As)) is doped into the p-type well region PWL in the n-type transistor region NTR and the polysilicon layer PLS1 on the n-type transistor region NTR. An n-type region LNR is formed in the n-type transistor region NTR. The second peak GPK2 of dopant concentration in the polysilicon layer PLS1 (see FIG. 6) is formed by the ion implantation step shown in FIG. 12. Since the p-type transistor region PTR and the electric fuse circuit region EFR are covered with a mask (not shown) during doping of the n-type dopant, the n-type dopant is not doped into the p-type transistor region PTR and the electric fuse circuit region EFR.

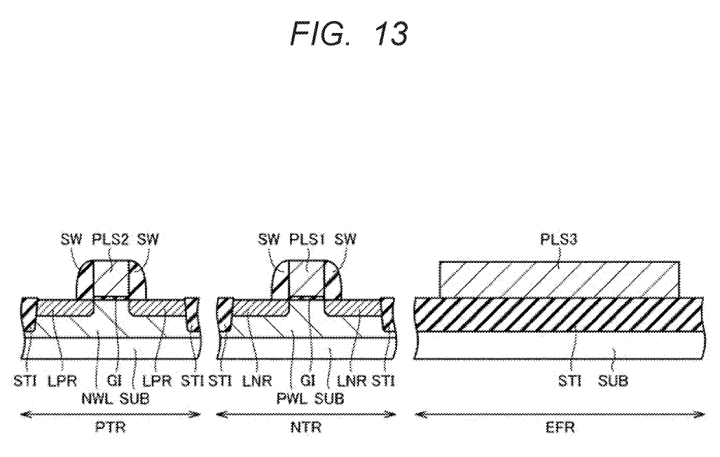

Referring to FIG. 13, sidewall spacers SW are formed on the side surfaces of the polysilicon layer PLS1 and the polysilicon layer PLS2. For example, using the CVD method, a silicon oxide film and a silicon nitride film are formed on the semiconductor substrate SUB to cover the polysilicon layer PLS1 and the polysilicon layer PLS2. An anisotropic etching process is used to process the silicon nitride film. The silicon oxide film formed on the upper surface of the polysilicon layer PLS1 and the upper surface of the polysilicon layer PLS2 is removed. Thus, sidewall spacers SW made from a silicon oxide film and a silicon nitride film are formed on the side surfaces of the polysilicon layer PLS1 and the polysilicon layer PLS2.

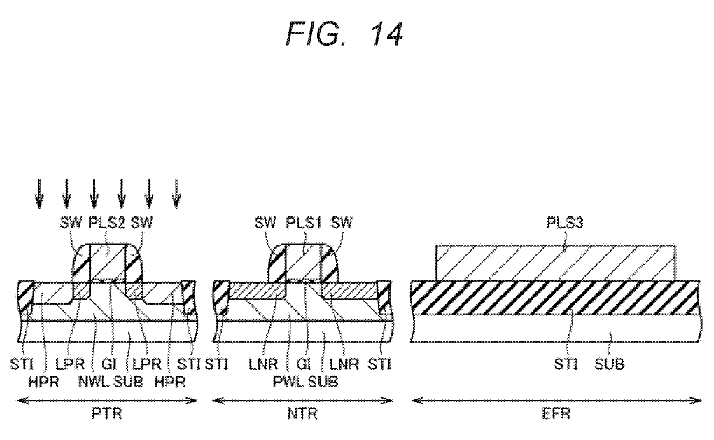

Referring to FIG. 14, using ion implantation method, p-type dopant (for example, boron (B)) is doped into the p-type region LPR in the p-type transistor region PTR and the polysilicon layer PLS2 on the p-type transistor region PTR. Since the n-type transistor region NTR and the electric fuse circuit region EFR are covered with a mask (not shown) during doping of the p-type dopant, the p-type dopant is not doped into the n-type transistor region NTR and the electric fuse circuit region EFR. Therefore, the average dopant concentration of the polysilicon layer PLS3 is lower than the average dopant concentration of the polysilicon layer PLS2. A p-type region HPR is formed in the p-type transistor region PTR. The first peak GPK1 of dopant concentration in the polysilicon layer PLS2 (see FIG. 6) is formed by the ion implantation step shown in FIG. 14.

The ion implantation energy in the ion implantation step shown in FIG. 14 is higher than the ion implantation energy in the ion implantation step shown in FIG. 11. Therefore, the p-type region HPR is formed deeper than the p-type region LPR. The dose amount in the ion implantation step shown in FIG. 14 is greater than the dose amount in the ion implantation step shown in FIG. 11. Therefore, the concentration of p-type dopant in the p-type region HPR is higher than the concentration of p-type dopant in the p-type region LPR. Thus, the dopant concentration distribution shown in FIG. 6 is formed in the polysilicon layer PLS2. Specifically, the depth at which the dopant concentration in the polysilicon layer PLS2 is maximized (the depth of the first peak GPK1) is deeper than the depth of the second peak GPK2 in the dopant concentration of the polysilicon layer PLS2 and the depth at which the dopant concentration in the polysilicon layer FPS is maximized (the depth of peak PPK).

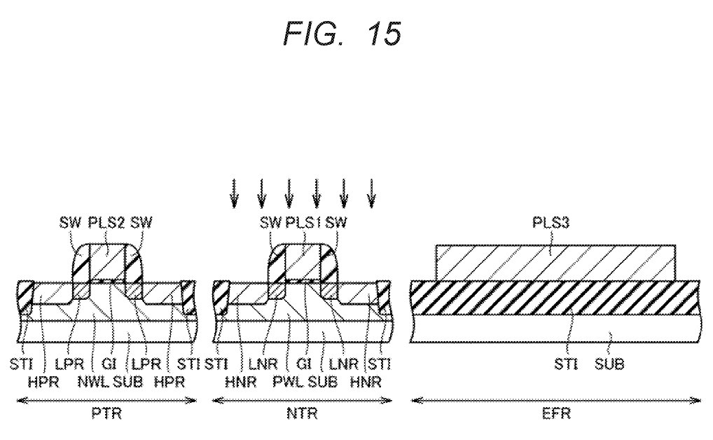

Referring to FIG. 15, n-type dopant (for example, Phosphorus (P) or Arsenic (As)) is doped into the n-type region LNR in the n-type transistor region NTR and the polysilicon layer PLS1 on the n-type transistor region NTR using the ion implantation method. Since the n-type dopant is doped while the p-type transistor region PTR and the electric fuse circuit region EFR are covered with a mask (not shown), the n-type dopant is not doped into the p-type transistor region PTR and the electric fuse circuit region EFR. Therefore, the average dopant concentration of the polysilicon layer PLS3 is lower than the average dopant concentration of the polysilicon layer PLS1. An n-type region HNR is formed in the n-type transistor region NTR. The first peak GPK1 of the dopant concentration in the polysilicon layer PLS1 (see FIG. 6) is formed by the ion implantation step shown in FIG. 15.

The ion implantation energy in the ion implantation step shown in FIG. 15 is higher than the ion implantation energy in the step shown in FIG. 12. Therefore, the n-type region HNR is formed deeper than the n-type region LNR. The dose amount in the ion implantation step shown in FIG. 15 is larger than the dose amount in the step shown in FIG. 12. Therefore, the concentration of n-type dopant in the n-type region HNR is higher than the concentration of n-type dopant in the n-type region LNR. In this way, the dopant concentration distribution shown in FIG. 6 is formed in the polysilicon layer PLS1. Specifically, the depth at which the dopant concentration of the polysilicon layer PLS1 is maximum (depth of the first peak GPK1) is deeper than the depth at which the dopant concentration of the second peak GPK2 of the polysilicon layer PLS1 and the depth at which the dopant concentration of the polysilicon layer FPS is maximum (depth of peak PPK).

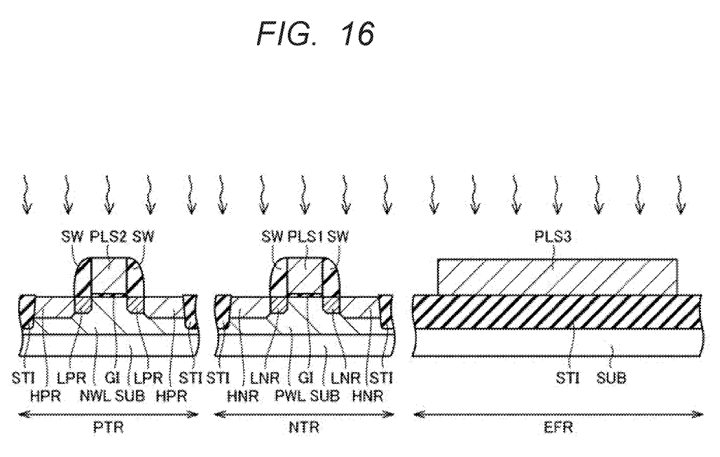

With reference to FIG. 16, annealing is applied to the p-type region HPR, the p-type region LPR, the n-type region HNR, the n-type region LNR, the polysilicon layer PLS1, the polysilicon layer PLS2, and the polysilicon layer PLS3. The dopant doped in the steps shown in FIGS. 11, 12, 14, and 15 are activated through annealing.

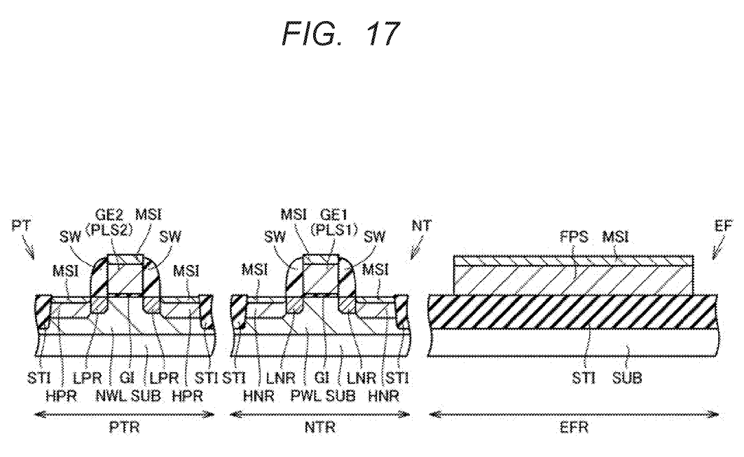

With reference to FIG. 17, a metal silicide layer MSI is formed on the p-type region HPR, the n-type region HNR, the polysilicon layer PLS1, the polysilicon layer PLS2, and the polysilicon layer PLS3. For example, a metal film (not shown) is formed on the n-type transistor region NTR, the p-type transistor region PTR, and the electric fuse circuit region EFR. The metal film is formed of cobalt, nickel, or nickel-platinum alloy, for example. By applying heat treatment to the metal film, the p-type region HPR, the n-type region HNR, the polysilicon layer PLS1, the polysilicon layer PLS2, and the polysilicon layer PLS3 react with the metal film. In this way, a metal silicide layer MSI is formed on the p-type region HPR, the n-type region HNR, the polysilicon layer PLS1, the polysilicon layer PLS2, and the polysilicon layer PLS3. Thereafter, the unreacted metal film is removed.

The portion of the polysilicon layer PLS1 not reacted with the metal film is the gate electrode GE1. The gate electrode GE1 is a polysilicon layer PLS1 containing n-type dopant. The portion of the polysilicon layer PLS2 not reacted with the metal film is the gate electrode GE2. The gate electrode GE2 is a polysilicon layer PLS2 containing p-type dopant. The portion of the polysilicon layer PLS3 not reacted with the metal film is the polysilicon layer FPS. The polysilicon layer FPS contains p-type dopant.

Through the above steps, the transistor NT, the transistor PT, and the electric fuse element EF are formed on the upper surface of the semiconductor substrate SUB.

Subsequently, through the following steps, the semiconductor device SC shown in FIGS. 2 and 5 is obtained. An interlayer insulating film ILF is formed on the transistor NT, the transistor PT, and the electric fuse element EF by the CVD method, for example. Using photolithography and etching process, contact holes are formed in the interlayer insulating film ILF. A conductive layer is formed in the contact holes and on the interlayer insulating film ILF. For example, a barrier metal film including titanium films or titanium nitride films, or these laminated films is formed. Then, a conductive film primarily formed of tungsten is formed on this barrier metal film. In this way, a conductive layer is obtained. By removing the conductive layer outside the contact holes by the CMP method, the plug PG is formed in the contact holes. The plug PG is connected to the metal silicide layer MSI. A wiring line (not shown) is formed on the interlayer insulating film ILF and the plug PG. Thus, the semiconductor device SC is obtained.

### OPERATION OF ELECTRIC FUSE ELEMENT EF

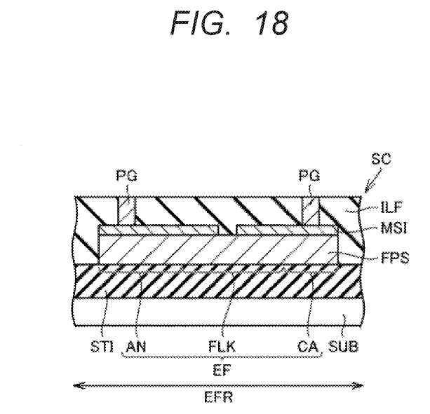

With reference to FIG. 3 and FIG. 18, the operation of the electric fuse element EF will be explained. When signal Vg is input to the gate electrode of the programming transistor PRT, the programming transistor PRT turns on. Current I flows through the fuse link FLK of the electric fuse element EF. The electric resistance of the metal silicide layer MSI is smaller than the electric resistance of the polysilicon layer FPS. Therefore, current I mainly flows through the metal silicide layer MSI. As a result, the material configuring the metal silicide layer MSI of the fuse link FLK moves. Causes of the material movement are not particularly limited, but can be illustrated by the following two reasons. The first cause is electromigration occurring in the metal silicide layer MSI of the fuse link FLK. Electromigration is a phenomenon in which, as the current density I flowing through the metal silicide layer MSI increases, the material configuring the metal silicide layer MSI moves due to electron flow. The second cause is the heating of the fuse link FLK by current I, causing some of the materials (e.g., Si) configuring the metal silicide layer MSI to melt and move.

Therefore, the metal silicide layer MSI is cut (see FIG. 18), or the density of the metal silicide materials configuring the metal silicide layer MSI locally decreases. The electric resistance of the metal silicide layer MSI becomes higher than the electric resistance of the polysilicon layer FPS. Current I mainly flows through the polysilicon layer FPS. In this way, the electric resistance of the electric fuse element EF (more specifically, fuse link FLK) increases. The determination circuit DEC determines the conduction state of the electric fuse element EF (change in electric resistance of the electric fuse element EF).

In the first embodiment, the conduction state of electric fuse element EF changes not by fusion of the polysilicon layer FPS of electric fuse element EF but by the movement of materials configuring the metal silicide layer MSI of electric fuse element EF. The current I required to move the materials configuring the metal silicide layer MSI of electric fuse element EF is smaller than the current I required to fuse the polysilicon layer FPS of electric fuse element EF. The current I needed to change the conduction state of electric fuse element EF can be reduced. As the current I handled by the programming transistor PRT decreases, the occupied area of the programming transistor PRT decreases.

Additionally, the average dopant concentration of the polysilicon layer FPS is lower than the average dopant concentration of the polysilicon layer PLS2 of the gate electrode GE2. Therefore, after the conduction state of the electric fuse element EF changes, the electric resistance of the electric fuse element EF increases significantly compared to the electric resistance before the conduction state changes. For instance, the electric resistance of electric fuse element EF after the conduction state changes is more than 10³ times greater than the electric resistance of electric fuse element EF after the conduction state changes. Thus, it is not necessary to use a high-precision sense amplifier circuit as the determination circuit DEC, and the occupied area of the determination circuit DEC decreases.

### MODIFIED EXAMPLE

In the first modification example of first embodiment, instead of p-type dopant in the polysilicon layer FPS, n-type dopant (such as phosphorus (P) or arsenic (As)) may be doped. The concentration of n-type dopant in the polysilicon layer FPS is lower than the concentration of n-type dopant in the polysilicon layer PLS1 of the gate electrode GE1. In the manufacturing method of semiconductor device SC in the first modification example of first embodiment, instead of the p-type dopant doping step shown in FIG. 11, the n-type dopant is doped into the polysilicon layer FPS during the n-type dopant doping step shown in FIG. 12.

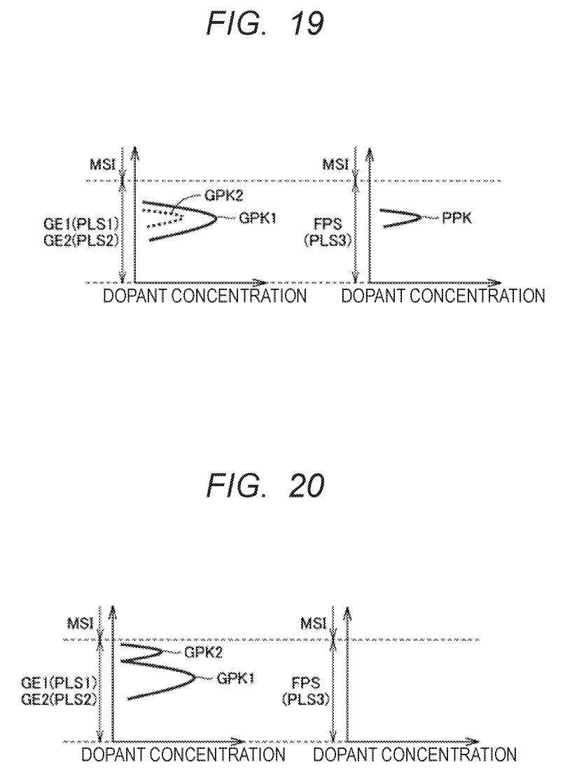

With reference to FIG. 19, in the second modification example of first embodiment, the depth of the first peak GPK1 may be equal to the depth of the second peak GPK2, and the polysilicon layer PLS2 of the gate electrode GE2 may have a single peak in dopant concentration in the thickness direction of the polysilicon layer PLS2. The concentration distribution of dopant in the polysilicon layer PLS2 in the second modification example is realized by changing the ion implantation conditions shown in FIGS. 11 and 14, as well as the annealing conditions shown in FIG. 16.

The effects of semiconductor device SC of first embodiment and its manufacturing method will be explained. The semiconductor device SC of first embodiment includes a transistor (e.g., transistor PT) and an electric fuse element EF. The transistor includes a gate electrode (e.g., gate electrode GE2). The gate electrode is the first polysilicon layer (e.g., polysilicon layer PLS2). The electric fuse element EF includes the second polysilicon layer (polysilicon layer FPS) and the metal silicide layer MSI formed on the second polysilicon layer. The average dopant concentration of the second polysilicon layer is lower than the average dopant concentration of the first polysilicon layer.

The average dopant concentration of the second polysilicon layer (polysilicon layer FPS) is lower than the average dopant concentration of the first polysilicon layer (e.g., polysilicon layer PLS2). Therefore, the difference between the electric resistance of the electric fuse element EF after its conduction state changes and the electric resistance of the electric fuse element EF before its conduction state changes increases. There is no need to use a high-precision sense amplifier circuit as the determination circuit DEC to determine the conduction state of the electric fuse element EF. The occupied area of the determination circuit DEC decreases. The semiconductor device SC is miniaturized.

In the semiconductor device SC of the first embodiment, the peak dopant concentration of the second polysilicon layer (polysilicon layer FPS) is lower than the peak dopant concentration of the first polysilicon layer (e.g., polysilicon layer PLS2).

Therefore, the difference between the electric resistance of the electric fuse element EF after the conduction state of the electric fuse element EF changes and the electric resistance of the electric fuse element EF before the conduction state of the electric fuse element EF changes increases. There is no need to use a high-precision sense amplifier circuit as the determination circuit DEC to determine the conduction state of the electric fuse element EF. The occupied area of the determination circuit DEC decreases. The semiconductor device SC is miniaturized.

The manufacturing method of the semiconductor device SC of the first embodiment includes forming a first polysilicon layer (e.g., polysilicon layer PLS2) and a second polysilicon layer (e.g., polysilicon layer PLS3 or polysilicon layer FPS) on the semiconductor substrate SUB. The average dopant concentration of the second polysilicon layer is lower than the average dopant concentration of the first polysilicon layer. The method includes forming a metal silicide layer MSI on the second polysilicon layer. The semiconductor device SC includes a transistor (e.g., transistor PT) and an electric fuse element EF. The first polysilicon layer is the gate electrode of the transistor (e.g., gate electrode GE2). The electric fuse element EF includes the second polysilicon layer and the metal silicide layer MSI.

The average dopant concentration of the second polysilicon layer (polysilicon layer FPS) is lower than the average dopant concentration of the first polysilicon layer (e.g., polysilicon layer PLS2). Therefore, the difference between the electric resistance of the electric fuse element EF after the conduction state of the electric fuse element EF changes and the electric resistance of the electric fuse element EF before the conduction state of the electric fuse element EF changes increases. There is no need to use a high-precision sense amplifier circuit as the determination circuit DEC to determine the conduction state of the electric fuse element EF. The occupied area of the determination circuit DEC decreases. The semiconductor device SC is miniaturized.

In the manufacturing method of the semiconductor device SC of the first embodiment, the peak dopant concentration of the second polysilicon layer is lower than the peak dopant concentration of the first polysilicon layer (e.g., polysilicon layer PLS2).

Therefore, the difference between the electric resistance of the electric fuse element EF after the conduction state of the electric fuse element EF changes and the electric resistance of the electric fuse element EF before the conduction state of the electric fuse element EF changes increases. There is no need to use a high-precision sense amplifier circuit as the determination circuit DEC to determine the conduction state of the electric fuse element EF. The occupied area of the determination circuit DEC decreases. The semiconductor device SC is miniaturized.

In the semiconductor device SC of the first embodiment and the manufacturing method of the semiconductor device SC, the sheet resistance of the second polysilicon layer (e.g., polysilicon layer PLS3 or polysilicon layer FPS) is greater than the sheet resistance of the first polysilicon layer (e.g., polysilicon layer PLS2 or gate electrode GE2).

Therefore, the difference between the electric resistance of the electric fuse element EF after the conduction state of the electric fuse element EF changes and the electric resistance of the electric fuse element EF before the conduction state of the electric fuse element EF changes increases. The occupied area of the determination circuit DEC further decreases. The semiconductor device SC is miniaturized.

### SECOND EMBODIMENT

Referring to FIGS. 1-5 and 20, the configuration of the semiconductor device SC of the second embodiment will be described. The semiconductor device SC of the second embodiment has a similar configuration to the semiconductor device SC of the first embodiment but differs mainly in the following points.

In the second embodiment, the polysilicon layer FPS of the electric fuse element EF is an undoped polysilicon layer, and is dopant-free. That is, the polysilicon layer FPS may inevitably contain dopant (e.g., the concentration of inevitable dopant is 1×10¹⁷ cm⁻³ or less), but intentional doping of dopant as shown in FIG. 11 is not performed on the polysilicon layer FPS. The dopant concentration of the polysilicon layer FPS is substantially zero.

### MANUFACTURING METHOD OF SEMICONDUCTOR DEVICE SC

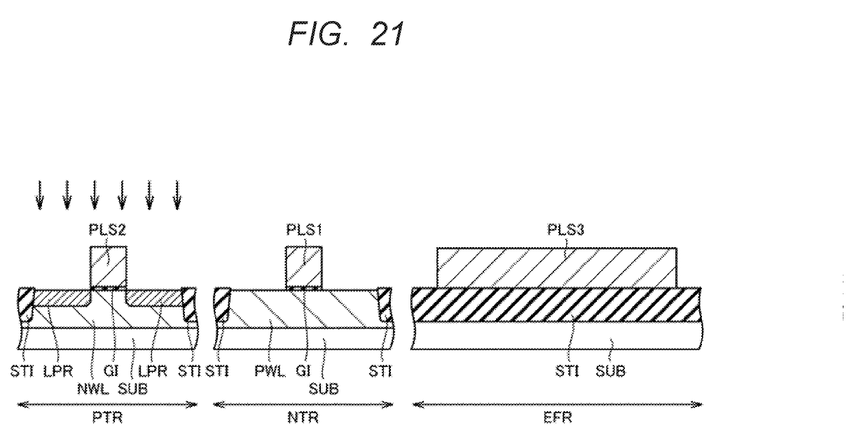

The manufacturing method of the semiconductor device SC of the second embodiment has a similar configuration to the manufacturing method of the semiconductor device SC of the first embodiment, but differs in that it includes the step shown in FIG. 21 in place of the step shown in FIG. 11. As shown in FIG. 21, in the manufacturing method of the semiconductor device SC of the second embodiment, the polysilicon layer PLS3 on the electric fuse circuit region EFR is covered with a mask (not shown). Therefore, dopant is not doped into the polysilicon layer PLS3 in the electric fuse circuit region EFR.

The semiconductor device SC of the second embodiment and the manufacturing method of the same additionally have the following effects to those of the semiconductor device SC of the first embodiment and the manufacturing method of the same.

In the semiconductor device SC of the second embodiment and the manufacturing method of the same, the second polysilicon layer (e.g., polysilicon layer PLS3 or polysilicon layer FPS) is an undoped polysilicon layer.

Therefore, the electric resistance of the polysilicon layer FPS in the second embodiment is greater than the electric resistance of the polysilicon layer FPS in the first embodiment. The difference between the electric resistance of the electric fuse element EF after the conduction state of the electric fuse element EF changes and the electric resistance of the electric fuse element EF before the conduction state of the electric fuse element EF changes further increases. The occupied area of the determination circuit DEC decreases. The semiconductor device SC is miniaturized.

### THIRD EMBODIMENT

Referring to FIGS. 1-6 , the configuration of the semiconductor device SC of the third embodiment will be described. The semiconductor device SC of the third embodiment has a similar configuration to the semiconductor device SC of the first embodiment but differs mainly in the following points.

In the third embodiment, the polysilicon layer FPS of the electric fuse element EF contains both n-type dopant and p-type dopant. In the third embodiment, the average dopant concentration of the polysilicon layer FPS is the absolute value of the difference between the average concentration of n-type dopant and the average concentration of p-type dopant in the polysilicon layer FPS. In this specification, the average concentration of n-type dopant in the polysilicon layer FPS is the average value of the concentration of n-type dopant in the thickness direction of the polysilicon layer FPS. The average concentration of p-type dopant in the polysilicon layer FPS is the average value of the concentration of p-type dopant in the thickness direction of the polysilicon layer FPS.

### MANUFACTURING METHOD OF SEMICONDUCTOR DEVICE SC

The manufacturing method of the semiconductor device SC of the third embodiment has a similar configuration to the manufacturing method of the semiconductor device SC of the first embodiment but differs mainly in the following points.

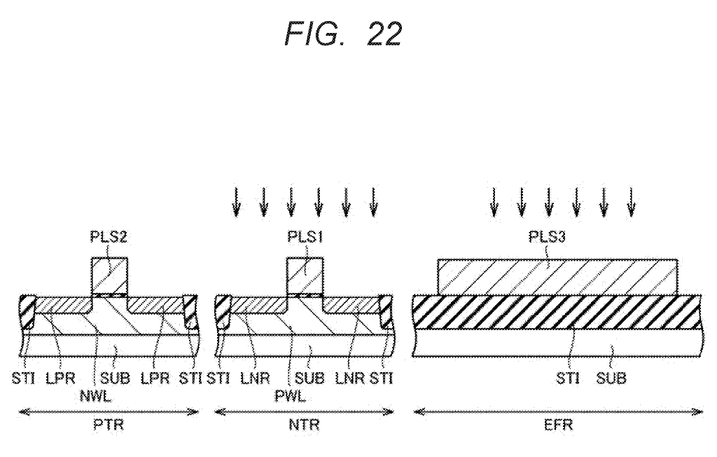

The manufacturing method of the semiconductor device SC of the third embodiment includes the step shown in FIG. 22 instead of the step shown in FIG. 12. Specifically, in addition to the polysilicon layer PLS1 on the n-type transistor region NTR, n-type dopant is doped into the polysilicon layer PLS3 in the electric fuse circuit region EFR. Thus, the polysilicon layer FPS contains both n-type and p-type dopant.

The semiconductor device SC of the third embodiment and the manufacturing method of the semiconductor device SC provide the following effects similar to those of the semiconductor device SC of the first embodiment and the manufacturing method of the semiconductor device SC.

In the semiconductor device SC of the third embodiment and the manufacturing method of the semiconductor device SC, the second polysilicon layer (polysilicon layer FPS) contains n-type dopant and p-type dopant. The average dopant concentration of the second polysilicon layer is the absolute value of the difference between the average concentration of n-type dopant and the average concentration of p-type dopant.

Therefore, the difference between the electric resistance of the electric fuse element EF after the conduction state of the electric fuse element EF changes and the electric resistance of the electric fuse element EF before the conduction state of the electric fuse element EF changes increases. There is no need to use a high-precision sense amplifier circuit as the determination circuit DEC to determine the conduction state of the electric fuse element EF. The occupied area of the determination circuit DEC decreases. The semiconductor device SC is miniaturized.

### FOURTH EMBODIMENT

Referring to FIGS. 1, 2, 4-6 and 23-25 the configuration of the semiconductor device SC of the fourth embodiment will be described. The semiconductor device SC of the fourth embodiment has a similar configuration to the semiconductor device SC of the first embodiment but differs mainly in the following points.

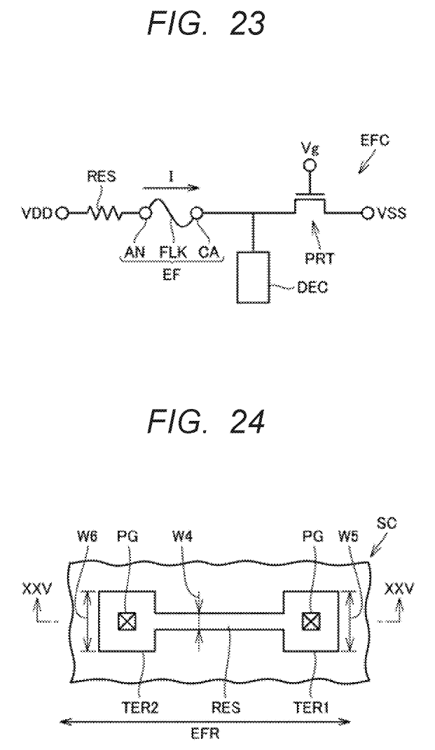

Referring to FIG. 23, the electric fuse circuit EFC of the semiconductor device SC of the fourth embodiment further includes an electric resistor RES, a terminal TER1, and a terminal TER2. The terminal TER1 is connected to the first end of the electric resistor RES. The terminal TER2 is connected to the second end of the electric resistor RES opposite the first end. The electric resistor RES is connected to the anode terminal AN of the electric fuse element EF via the terminal TER1. The resistor RES is connected to the power supply voltage VDD via the terminal TER2.

The width W4 of the resistor RES is smaller than the width W5 of the terminal TER1 and the width W6 of the terminal TER2. The width W4 of the resistor RES is the length in the short direction of the resistor RES in plan view on the upper surface of the semiconductor substrate SUB. The width W4 of the resistor RES is the length in the short direction of the resistor RES in plan view on the upper surface of the semiconductor substrate SUB. The width W5 of the terminal TER1 is the length in the short direction of the terminal TER1 in plan view on the upper surface of the semiconductor substrate SUB. The width W6 of the terminal TER2 is the length in the short direction of the terminal TER2 in plan view on the upper surface of the semiconductor substrate SUB.

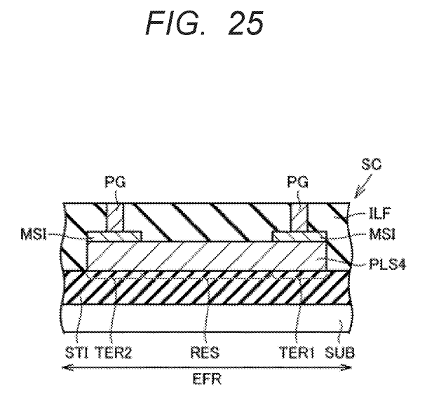

Referring to FIGS. 24 and 25, in addition to the electric fuse element EF (see FIG. 4), the resistor RES, the terminal TER1, and the terminal TER2 are further formed on the element isolation region STI in the electric fuse circuit region EFR. The terminal TER1 and the terminal TER2 each include a polysilicon layer PLS4 and a metal silicide layer MSI. The resistor RES includes a polysilicon layer PLS4 but does not include a metal silicide layer MSI.

The polysilicon layer PLS4 is a polysilicon layer doped with at least one of p-type dopant (e.g., boron (B)) or n-type dopant (e.g., phosphorus (P) or arsenic (As)) and has conductivity. The polysilicon layer PLS4 is formed on the element isolation region STI. The width W4 of the resistor RES is greater than the width W1 of the fuse link FLK (see FIG. 4). Therefore, when a current I is applied to the electric fuse circuit EFC, the resistor RES is prevented from fusing before the electric resistance of the electric fuse element EF changes.

The metal silicide layer MSI is formed on the polysilicon layer PLS4. The polysilicon layer PLS4 is formed between the element isolation region STI and the metal silicide layer MSI. The electric resistance of the metal silicide layer MSI is smaller than the electric resistance of the polysilicon layer PLS4.

Referring to FIGS. 2 and 5, an interlayer insulating film ILF is formed on the resistor RES, the terminal TER1, and the terminal TER2. The interlayer insulating film ILF is, for example, a silicon oxide film. Contact holes are formed in the interlayer insulating film ILF. Plugs PG are formed in the contact holes. The plug PG is connected to the metal silicide layer MSI. The plug PG is electrically connected to the resistor RES via the metal silicide layer MSI, the terminal TER1, and the terminal TER2. A wiring line (not shown) is formed on the interlayer insulating film ILF and the plug PG.

The manufacturing step of the resistor RES is similar to the manufacturing step of the electric fuse element EF but mainly differs in the dopant doping step. For example, in addition to the step shown in FIG. 11, in the step shown in FIG. 14, the dopant is doped into the polysilicon layer PLS4 of the resistor RES.

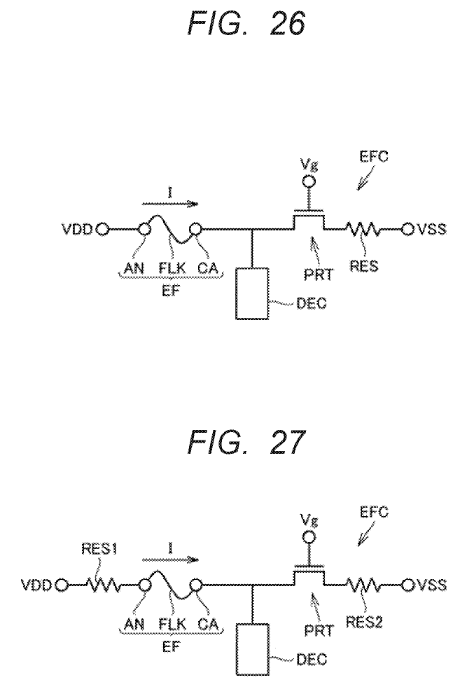

Referring to FIG. 26, in the first modified example of the fourth embodiment, the resistor RES is connected to the programming transistor PRT. The resistor RES is electrically connected to the cathode terminal CA of the electric fuse element EF, for example, via the programming transistor PRT. Specifically, the resistor RES is connected to the ground potential VSS via the terminal TER1 and to the programming transistor PRT via the terminal TER2.

Referring to FIG. 27, in the second modified example of the fourth embodiment, the electric fuse circuit EFC may include a resistor RES1 and a resistor RES2. Each of the resistor RES1 and the resistor RES2 have a similar configuration as the resistor RES shown in FIGS. 24 and 25. The resistor RES1 is connected to the anode terminal AN of the electric fuse element EF, similar to the resistor RES shown in FIG. 23. The resistor RES2 is connected to the programming transistor PRT, similar to the resistor RES shown in FIG. 26.

The semiconductor device SC of the fourth embodiment and the manufacturing method of the semiconductor device SC provide the following effects in addition to the effects of the semiconductor device SC of the first embodiment and the manufacturing method of the semiconductor device SC.

The semiconductor device SC of the fourth embodiment further includes a resistor RES connected to the electric fuse element EF.

The resistor RES mitigates the abrupt rise of the current I applied to the electric fuse element EF. Therefore, the electric resistance of the electric fuse element EF can be varied under broader conditions (e.g., power supply voltage VDD and signal Vg).

In the semiconductor device SC of the fourth embodiment, the resistor RES includes the third polysilicon layer (polysilicon layer PLS4). The electric fuse element EF includes the fuse link FLK. The width W4 of the third polysilicon layer is greater than the width W1 of the second polysilicon layer of the fuse link FLK.

Therefore, when current is applied to the electric fuse element EF to change the conduction state of the electric fuse element EF, the resistor RES is prevented from fusing before the electric fuse element EF (more specifically, the fuse link FLK).

The manufacturing method of the semiconductor device SC of the fourth embodiment further includes forming the resistor RES connected to the electric fuse element EF.

The resistor RES mitigates the abrupt rise of the current I applied to the electric fuse element EF. Therefore, the electric resistance of the electric fuse element EF can be varied under broader conditions (e.g., power supply voltage VDD and signal Vg).

In the manufacturing method of the semiconductor device SC of the fourth embodiment, forming the resistor RES includes forming the third polysilicon layer (polysilicon layer PLS4). The electric fuse element EF includes the fuse link FLK. The average dopant concentration of the third polysilicon layer is greater than or equal to the average dopant concentration of the second polysilicon layer (e.g., polysilicon layer PLS3 or polysilicon layer FPS). The width W4 of the third polysilicon layer is greater than the width W1 of the second polysilicon layer of the fuse link FLK.

Therefore, when current is applied to the electric fuse element EF to change the conduction state of the electric fuse element EF, the resistor RES is prevented from fusing before the electric fuse element EF (more specifically, the fuse link FLK).

### FIFTH EMBODIMENT

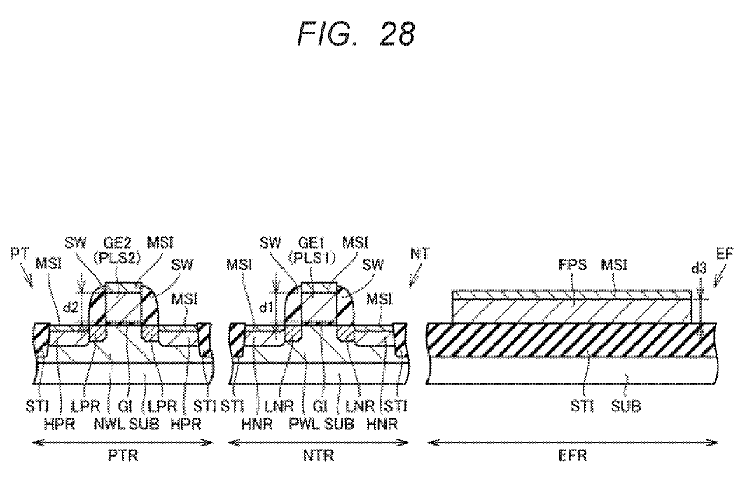

Referring to FIGS. 1, 3, 4, 6 and 28, the configuration of the semiconductor device SC of the fifth embodiment will be explained. The semiconductor device SC of the fifth embodiment shares a similar configuration with the semiconductor device SC of the first embodiment, but mainly differs in the following points.

The thickness d3 of the polysilicon layer FPS is smaller than the thickness d1 of gate electrode GE1 and the thickness d2 of gate electrode GE2.

The manufacturing method of the semiconductor device SC of the fifth embodiment includes similar steps to the manufacturing method of the semiconductor device SC of the first embodiment but mainly differs in the following points.

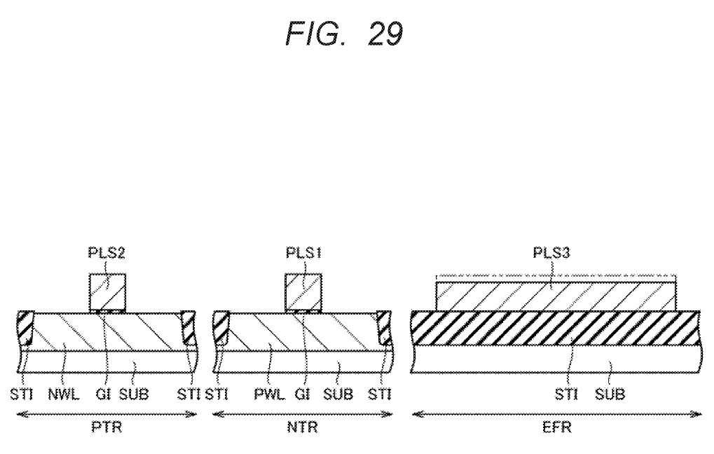

As shown in FIG. 10, the polysilicon layer PLS1, the polysilicon layer PLS2, and the polysilicon layer PLS3 are formed. Then, as shown in FIG. 29, the polysilicon layer PLS3 on the electric fuse circuit region EFR is etched to reduce the thickness of the polysilicon layer PLS3. In the step shown in FIG. 29, the polysilicon layer PLS1 on the n-type transistor region NTR and the polysilicon layer PLS2 on the p-type transistor region PTR are not etched. Then, the steps shown in FIGS. 11-17 are carried out. Thus, the semiconductor device SC of the fifth embodiment is obtained.

The semiconductor device SC of the fifth embodiment and the manufacturing method of the semiconductor device SC provide the following effects in addition to the effects of the semiconductor device SC of the first embodiment and the manufacturing method of the semiconductor device SC.

In the semiconductor device SC of the fifth embodiment and the manufacturing method of the semiconductor device SC, the thickness (d3) of the second polysilicon layer (e.g., polysilicon layer PLS3 or polysilicon layer FPS) is smaller than the thickness (e.g., d2) of the first polysilicon layer (e.g., polysilicon layer PLS2 or gate electrode GE2).

Therefore, the sheet resistance of the second polysilicon layer (e.g., polysilicon layer PLS3 or polysilicon layer FPS) increases. The difference between the electric resistance of the electric fuse element EF after the conduction state of the electric fuse element EF changes and the electric resistance of the electric fuse element EF before the conduction state of the electric fuse element EF changes further increases. The occupied area of the determination circuit DEC further decreases. The semiconductor device SC is miniaturized.

### SIX EMBODIMENT

Referring to FIGS. 1- 6, the configuration of the semiconductor device SC of the sixth embodiment will be explained. The semiconductor device SC of the sixth embodiment shares a similar configuration with the semiconductor device SC of the first embodiment but mainly differs in the following points.

The polysilicon layer PLS1 of the gate electrode GE1 contains dopant (e.g., n-type dopant). The polysilicon layer PLS2 of the gate electrode GE2 contains dopant (e.g., p-type dopant). The polysilicon layer PLS3 contains dopant (for example, p-type dopant). The activation rate of dopant contained in the polysilicon layer FPS is lower than the activation rate of the dopant contained in the polysilicon layer PLS1. The activation rate of dopant contained in the polysilicon layer FPS is lower than the activation rate of the dopant contained in the polysilicon layer PLS2.

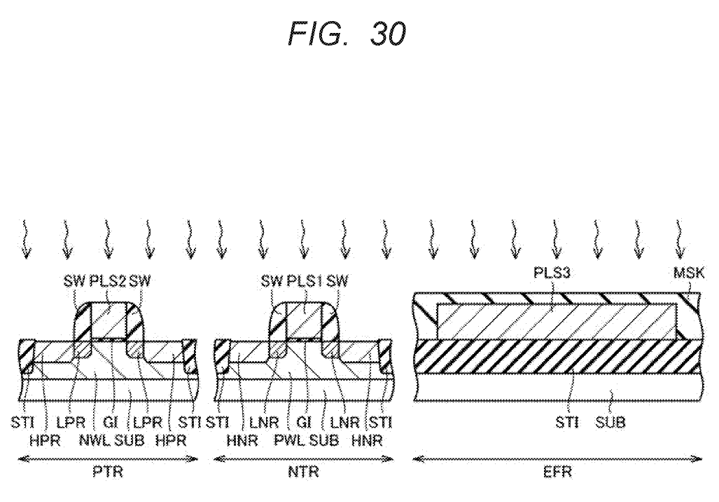

The manufacturing method of the semiconductor device SC in sixth embodiment includes the same steps as the manufacturing method of the semiconductor device SC in the first embodiment, but differs in that the method includes the annealing step shown in FIG. 30 instead of the annealing step shown in FIG. 16 of the first embodiment.

Referring to FIG. 30, before performing the annealing step, the polysilicon layer PLS3 on the electric fuse circuit region EFR is covered with a mask MSK. Then, the annealing step is performed on the p-type region HPR, the p-type region LPR, the n-type region HNR, the n-type region LNR, the polysilicon layer PLS1, the polysilicon layer PLS2, and the polysilicon layer PLS3. Since the polysilicon layer PLS3 is covered with the mask MSK, it is less likely to be heated than the polysilicon layer PLS1 and the polysilicon layer PLS2. Therefore, the activation rate of dopant contained in the polysilicon layer PLS3 is lower than the activation rate of dopant contained in the polysilicon layer PLS1 and the polysilicon layer PLS2.

The semiconductor device SC of the sixth embodiment and the manufacturing method of the semiconductor device SC provide the following effects in addition to the effects of the semiconductor device SC and the manufacturing method of the semiconductor device SC in the first embodiment.

In the semiconductor device SC of the sixth embodiment, the first polysilicon layer (for example, polysilicon layer PLS2 or gate electrode GE2) contains the first dopant (for example, p-type dopant). The second polysilicon layer (for example, polysilicon layer PLS3 or polysilicon layer FPS) contains the second dopant (for example, p-type dopant). The activation rate of the second dopant is lower than the activation rate of the first dopant.

Therefore, the sheet resistance of the second polysilicon layer (for example, polysilicon layer PLS3 or polysilicon layer FPS) increases. The difference between the electric resistance of the electric fuse element EF after the conduction state of the electric fuse element EF changes and the electric resistance of the electric fuse element EF before the conduction state of the electric fuse element EF changes further increases. The occupied area of the decision circuit DEC further decreases. The semiconductor device SC is miniaturized.

The manufacturing method of the semiconductor device SC in the sixth embodiment further includes annealing the first polysilicon layer (for example, polysilicon layer PLS2 or gate electrode GE2) and the second polysilicon layer (for example, polysilicon layer PLS3 or polysilicon layer FPS) to activate the first dopant and the second dopant. The first polysilicon layer contains the first dopant (for example, p-type dopant). The second polysilicon layer contains the second dopant (for example, p-type dopant). The activation rate of the second dopant is lower than the activation rate of the first dopant.

Therefore, the sheet resistance of the second polysilicon layer (for example, polysilicon layer PLS3 or polysilicon layer FPS) increases. The difference between the electric resistance of the electric fuse element EF after the conduction state of the electric fuse element EF changes and the electric resistance of the electric fuse element EF before the conduction state of the electric fuse element EF changes further increases. The occupied area of the decision circuit DEC further decreases. The semiconductor device SC is miniaturized.

### SEVENTH EMBODIMENT

Referring to FIGS. 1, 31, and 32, the semiconductor device SC of the seventh embodiment is described. The semiconductor device SC of the seventh embodiment has a similar configuration as the semiconductor device SC of the first embodiment but differs mainly in the following points.

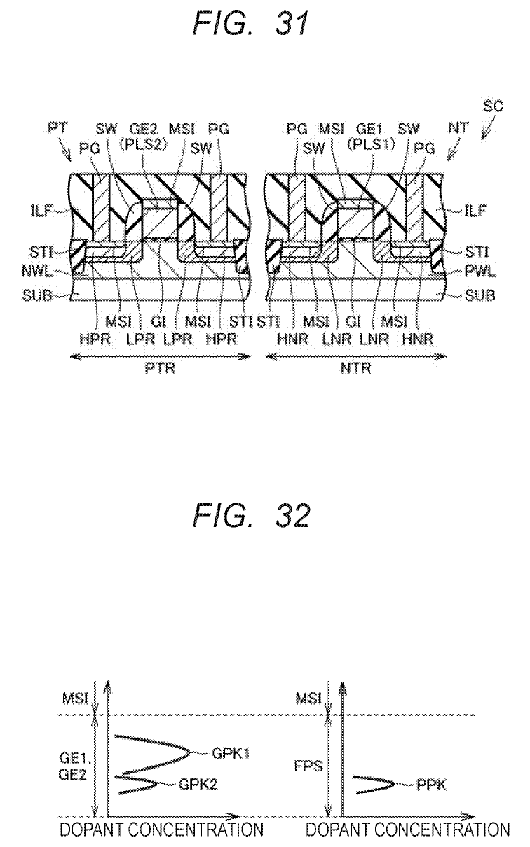

Referring to FIG. 31, the n-type region HNR is formed between the element isolation region STI and the sidewall spacer SW. The n-type region LNR is formed deeper than the n-type region HNR. The n-type region LNR is formed under the n-type region HNR and under the sidewall spacer SW. The n-type region LNR is formed between the element isolation region STI and the gate insulating film GI. The transistor NT has a DDD (Double Diffused Drain) structure.

The p-type region HPR is formed between the element isolation region STI and the sidewall spacer SW. The p-type region LPR is formed deeper than the p-type region HPR. The p-type region LPR is formed under the p-type region HPR and under the sidewall spacer SW. The p-type region LPR is formed between the element isolation region STI and the gate insulating film GI. The transistor PT has a DDD structure.

Referring to FIG. 32, the depth at which the dopant concentration of the polysilicon layer FPS is at its maximum (depth of peak PPK) is deeper than the depth at which the dopant concentration of the polysilicon layer PLS2 of the gate electrode GE2 is at its maximum (depth of first peak GPK1). The depth of second peak GPK2 is similar to the depth of peak PPK and is deeper than the depth of first peak GPK1. The distribution of dopant (n-type dopant) in the polysilicon layer PLS1 of gate electrode GE1 is similar to the distribution of dopant (p-type dopant) in the polysilicon layer PLS2 of gate electrode GE2.

### MANUFACTURING METHOD OF SEMICONDUCTOR DEVICE SC

Referring to FIGS. 7-10 and 33-39, the manufacturing method of the semiconductor device SC in the seventh embodiment is described. The manufacturing method of the semiconductor device SC in the seventh embodiment includes similar steps as the manufacturing method of the semiconductor device SC in the first embodiment but mainly differs in the following points.

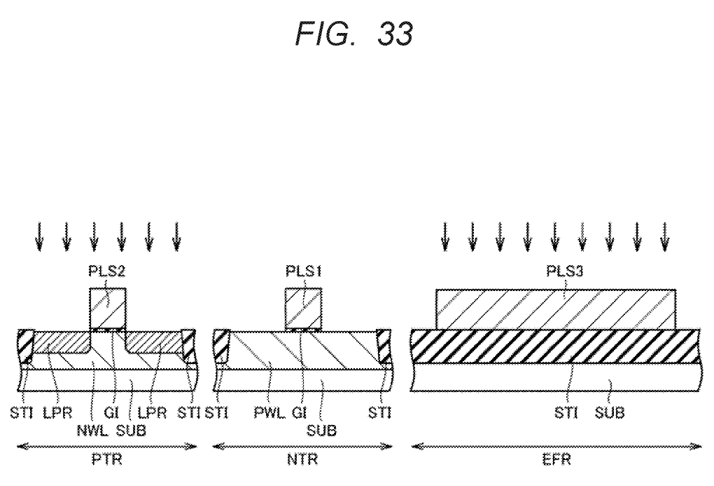

Following the steps shown in FIGS. 7-10 , as shown in FIG. 33, using ion implantation method, p-type dopant (for example, Boron (B)) is doped into the n-type well region NWL and the polysilicon layer PLS2 of the p-type transistor region PTR and the polysilicon layer PLS3 of the electric fuse circuit region EFR. The p-type region LPR is formed in the p-type transistor region PTR. The peak PPK of dopant concentration in the polysilicon layer FPS (refer to FIG. 32) and the second peak GPK2 of dopant concentration in the gate electrode GE2 (refer to FIG. 32) are formed by the ion implantation step shown in FIG. 33. The ion implantation step shown in FIG. 33 is similar to the ion implantation step shown in FIG. 11, but the p-type region LPR is formed more deeply in the p-type transistor region PTR.

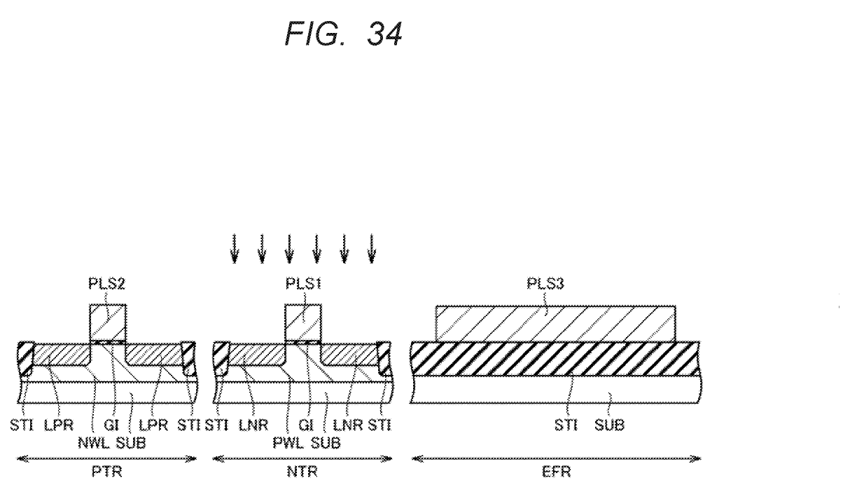

As shown in FIG. 34, using ion implantation method, n-type dopant (for example, Phosphorous (P) or Arsenic (As)) is doped into the p-type well region PWL and the polysilicon layer PLS1 of the n-type transistor region NTR. The n-type region LNR is formed in the n-type transistor region NTR. The second peak GPK2 of dopant concentration in the polysilicon layer PLS1 of the gate electrode GE1 (refer to FIG. 32) is formed by the ion implantation step shown in FIG. 12. The ion implantation step shown in FIG. 34 is similar to the ion implantation step shown in FIG. 12, but the n-type region LNR is formed more deeply in the n-type transistor region NTR.

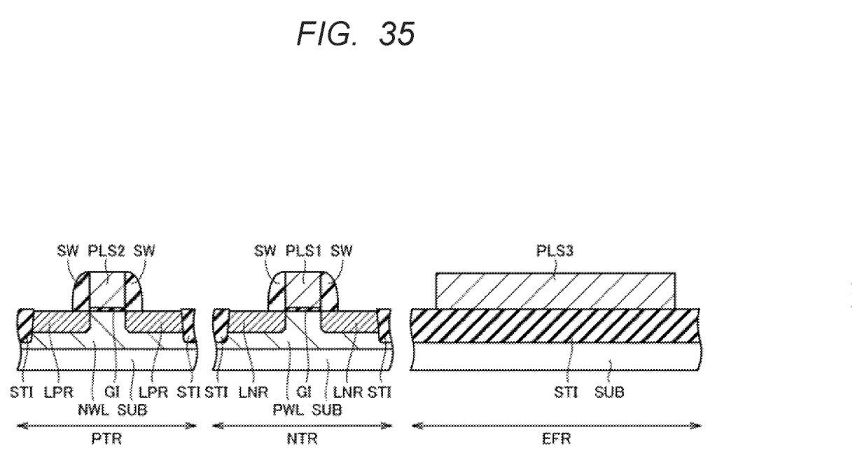

Referring to FIG. 35, the sidewall spacer SW is formed on the side surface of the polysilicon layer PLS1 and the side surface of the polysilicon layer PLS2. The step shown in FIG. 35 is similar to the step shown in FIG. 13.

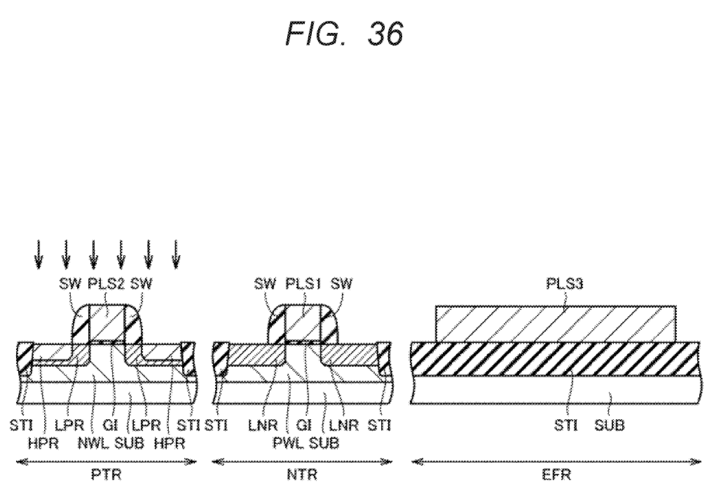

Referring to FIG. 36, using ion implantation method, p-type dopant (for example, Boron (B)) is doped into the p-type region LPR and the polysilicon layer PLS2 of the p-type transistor region PTR. The p-type region HPR is formed in the p-type transistor region PTR. The first peak GPK1 of dopant concentration in the polysilicon layer PLS2 (refer to FIG. 32) is formed by the ion implantation step shown in FIG. 36. The ion implantation step shown in FIG. 36 is similar to the ion implantation step shown in FIG. 33, but the p-type region HPR is formed more shallowly in the p-type transistor region PTR. Thus, the dopant concentration distribution shown in FIG. 32 is formed in the polysilicon layer PLS2.

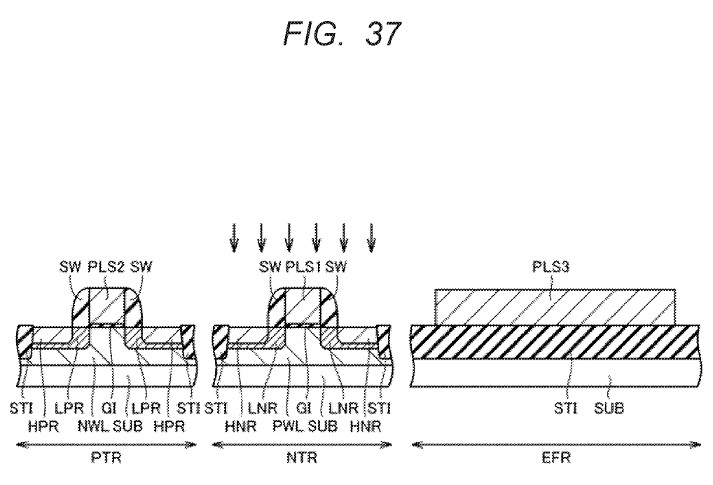

Referring to FIG. 37, using ion implantation method, n-type dopant (for example, Phosphorous (P) or Arsenic (As)) is doped into the n-type region LNR and the polysilicon layer PLS1 of the n-type transistor region NTR. The n-type region HNR is formed in the n-type transistor region NTR. The first peak GPK1 of dopant concentration in the polysilicon layer PLS1 (refer to FIG. 32) is formed by the ion implantation step shown in FIG. 37. The ion implantation step shown in FIG. 37 is similar to the ion implantation step shown in FIG. 34, but the n-type region HNR is formed more shallowly in the n-type transistor region NTR. Thus, the dopant concentration distribution shown in FIG. 32 is formed in the polysilicon layer PLS1.

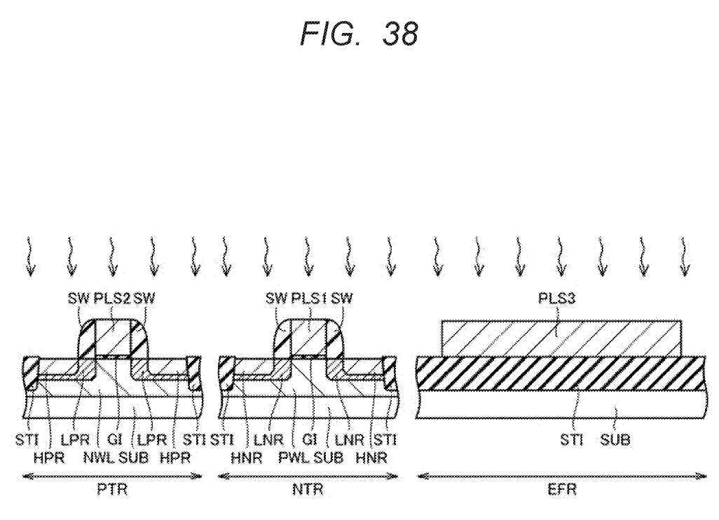

Referring to FIG. 38, annealing treatment is performed on the p-type region HPR, the p-type region LPR, the n-type region HNR, the n-type region LNR, the polysilicon layer PLS1, the polysilicon layer PLS2, and the polysilicon layer PLS3. The dopant doped in the steps shown in FIGS. 34, 35, 37, and 38 are activated by annealing treatment. The step shown in FIG. 38 is similar to the step shown in FIG. 16.

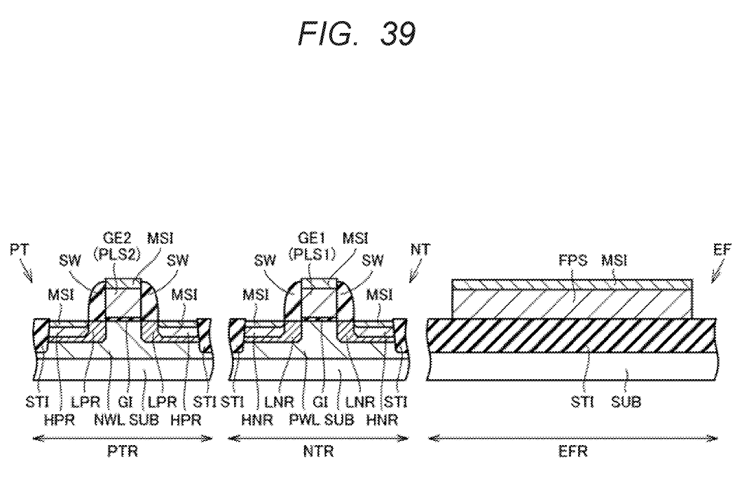

Referring to FIG. 39, the metal silicide layer MSI is formed on the p-type region HPR, the n-type region HNR, the polysilicon layer PLS1, the polysilicon layer PLS2, and the polysilicon layer PLS3. The step shown in FIG. 39 is similar to the step shown in FIG. 17. Then, as in the first embodiment, an interlayer insulating film ILF, a plug PG, and a wiring line (not shown) are formed. Thus, the semiconductor device SC of the seventh embodiment is obtained.

The semiconductor device SC of the seventh embodiment and the manufacturing method of the semiconductor device SC provide the following effects in addition to the effects of the semiconductor device SC of the first embodiment and the manufacturing method of the semiconductor device SC.

In the semiconductor device SC of the embodiment, the peak position of the concentration of the second dopant in the second polysilicon layer (polysilicon layer FPS) in the thickness direction of the semiconductor substrate SUB is closer to the semiconductor substrate SUB than the peak position of the concentration of the first dopant in the first polysilicon layer (e.g., polysilicon layer PLS2) in the thickness direction of the semiconductor substrate SUB. That is, the distance between the peak position of the concentration of the second dopant in the second polysilicon layer and the lower surface of the second polysilicon layer in the thickness direction of the semiconductor substrate SUB is smaller than the distance between the peak position of the concentration of the second dopant in the second polysilicon layer and the upper surface of the second polysilicon layer.

When a current I is applied to the electric fuse element EF to change the conduction state of the electric fuse element EF, the metal silicide layer MSI of the electric fuse element EF generates heat. The peak position of the concentration of the second dopant in the second polysilicon layer (polysilicon layer FPS) is remote from the metal silicide layer MSI. Therefore, thermal diffusion of the second dopant due to this heat is reduced. Variations in the electric resistance of the electric fuse element EF after the conduction state changes are reduced. The difference between the electric resistance of the electric fuse element EF after the conduction state changes and that before the conduction state changes becomes stably large. A highly accurate sense amplifier circuit is not required as the determination circuit DEC for determining the conduction state of the electric fuse element EF, reducing the occupied area of the determination circuit DEC. The semiconductor device SC is miniaturized.

Although the invention made by the present inventor has been specifically described based on the embodiment, the present invention is not limited to the as described above embodiment, and it is needless to say that various modifications can be made without departing from the gist thereof.

What is claimed is:

1. A semiconductor device comprising:
a transistor; and
an electric fuse element,
wherein the transistor comprises a gate electrode,
wherein the gate electrode is a first polysilicon layer,
wherein the electric fuse element comprises:
a second polysilicon layer; and
a metal silicide layer formed on the second polysilicon layer, and
wherein an average dopant concentration of the second polysilicon layer is lower than an average dopant concentration of the first polysilicon layer.

2. The semiconductor device according to claim 1,
wherein a peak dopant concentration of the second polysilicon layer is lower than a peak dopant concentration of the first polysilicon layer.

3. The semiconductor device according to claim 1,
wherein the second polysilicon layer is an undoped polysilicon layer.

4. The semiconductor device according to claim 1,
wherein the second polysilicon layer comprises n-type dopant and p-type dopant, and
wherein the average dopant concentration of the second polysilicon layer is an absolute value of a difference between an average concentration of the n-type dopant and an average concentration of the p-type dopant.

5. The semiconductor device according to claim 1, comprising:
an electric resistor connected to the electric fuse element.

6. The semiconductor device according to claim 5,
wherein the electric resistor comprises a third polysilicon layer,
wherein the electric fuse element comprises a fuse link, and
wherein a width of the third polysilicon layer is greater than a width of the second polysilicon layer of the fuse link.

7. The semiconductor device according to claim 1,
wherein a sheet resistance of the second polysilicon layer is greater than a sheet resistance of the first polysilicon layer.

8. The semiconductor device according to claim 7,
wherein a thickness of the second polysilicon layer is smaller than a thickness of the first polysilicon layer.

9. The semiconductor device according to claim 7,
wherein the first polysilicon layer comprises first dopant,
wherein the second polysilicon layer comprises second dopant, and
wherein an activation rate of the second dopant is lower than an activation rate of the first dopant.

10. A method of manufacturing a semiconductor device, the method comprising:
forming a first polysilicon layer and a second polysilicon layer on a semiconductor substrate,
wherein an average dopant concentration of the second polysilicon layer is lower than an average dopant concentration of the first polysilicon layer,
forming a metal silicide layer on the second polysilicon layer,
wherein the semiconductor device comprises a transistor and an electric fuse element,
wherein the first polysilicon layer is a gate electrode of the transistor, and
wherein the electric fuse element comprises the second polysilicon layer and the metal silicide layer.

11. The method according to claim 10,
wherein a peak dopant concentration of the second polysilicon layer is lower than a peak dopant concentration of the first polysilicon layer.

12. The method according to claim 10,
wherein the second polysilicon layer is an undoped polysilicon layer.

13. The method according to claim 10,
wherein the second polysilicon layer comprises n-type dopant and p-type dopant, and
wherein the average dopant concentration of the second polysilicon layer is an absolute value of a difference between an average concentration of the n-type dopant and an average concentration of the p-type dopant.

14. The method according to claim 10, comprising:
forming an electric resistor connected to the electric fuse element.

15. The method according to claim 14,
wherein forming the electric resistor comprises forming a third polysilicon layer,
wherein the electric fuse element comprises a fuse link,
wherein an average dopant concentration of the third polysilicon layer is equal to or greater than the average dopant concentration of the second polysilicon layer, and
wherein a width of the third polysilicon layer is greater than a width of the second polysilicon layer of the fuse link.

16. The method according to claim 10,
wherein a sheet resistance of the second polysilicon layer is greater than a sheet resistance of the first polysilicon layer.

17. The method according to claim 16,
wherein a thickness of the second polysilicon layer is smaller than a thickness of the first polysilicon layer.

18. The method according to claim 16, comprising:
annealing the first polysilicon layer and the second polysilicon layer,
wherein the first polysilicon layer comprises first dopant,
wherein the second polysilicon layer comprises second dopant, and
wherein an activation rate of the second dopant is lower than an activation rate of the first dopant.
